(19) United States
(12) Patent Application Publication
(10) Pub. No.: US 2013/0001797 A1
(43) Pub. Date: Jan. 3, 2013

(54) PACKAGE ON PACKAGE USING THROUGH SUBSTRATE VIAS

(76) Inventors: Yun-seok Choi, Hwaseong-si (KR); Hee-seok Lee, Yongin-si (KR); Tae-je Cho, Hwaseong-si (KR)

(21) Appl. No.: 13/531,289

(22) Filed: Jun. 22, 2012

(30) Foreign Application Priority Data
Jun. 28, 2011 (KR) 10-2011-0063034

(51) Int. Cl. H01L 23/498

(52) U.S. Cl. 257/774; 257/E23.067

(57) ABSTRACT

A package on package (PoP) employing a through substrate via (TSV) technique in order to reduce the size of a semiconductor chip, has vertically narrow pitches, and forms a higher number of connection terminals. The PoP include a first substrate with a recess disposed in a first surface of the substrate, and a semiconductor chip disposed at the recess. The PoP also includes a semiconductor package connected to the first semiconductor package. The first substrate includes TSVs for electronically connecting the semiconductor package and the semiconductor chip, and routing lines for re-distributing the signals/and or power transmitted via the TSVs.

### CROSS-REFERENCE TO RELATED APPLICATIONS

This U.S. non-provisional patent application claims priority under 35 U.S.C. 119 to Korean Patent Application No. 10-2011-0063034, filed on Jun. 28, 2011, the entirety of which is incorporated herein by reference. U.S. patent application Ser. No. 13/188,554, filed on Jul. 22, 2011, is also incorporated herein by reference in its entirety.

### BACKGROUND

A package on package (PoP) semiconductor package is a semiconductor package in which an upper semiconductor package and a lower semiconductor package are vertically stacked to increase the degree of integration of a semiconductor device. The improvement of the integration degree of a semiconductor device may be achieved by a wafer manufacturing process.

### SUMMARY

The disclosure provides a package on package (PoP) employing a through substrate via (TSV) technique in order to reduce the size of a semiconductor chip.

In one embodiment, a package on package semiconductor package (PoP) comprises a first substrate, the first substrate having a first surface, a second surface opposite the first surface, and a redistribution layer comprising a plurality of rerouting lines; a plurality of first conductive terminals disposed at the first surface; a recess disposed at the second surface; a semiconductor chip disposed at the recess, the semiconductor chip comprising a first surface and a second surface opposite the first surface, wherein the first surface of the semiconductor chip opposes the second surface of the first substrate; and a first semiconductor package electrically connected to the first substrate, the first semiconductor package comprising a second substrate, the second substrate having a first surface and a second surface, wherein the first surface of the second substrate opposes the second surface of the semiconductor chip, and wherein a height of the recess is at least 50% of a height of the semiconductor chip.

In one embodiment, a package on package semiconductor package (PoP) comprises a first semiconductor package comprising: a first substrate, the first substrate having a first surface, a second surface opposite the first surface, a redistribution layer comprising a plurality of rerouting lines, and a plurality of first through substrate vias (TSVs) extending therethrough; a plurality of first conductive terminals disposed at the first surface; a depression disposed at the second surface, the opening disposed at a center of the second surface; and a semiconductor chip disposed at the depression, the semiconductor chip comprising a first surface and a second surface opposite the first surface, wherein the first surface of the semiconductor chip opposes the second surface of the first substrate; and a second semiconductor package electrically connected to the first substrate, the second semiconductor package comprising a second substrate, the second substrate having a first surface and a second surface, wherein the first surface of the second substrate opposes the second surface of the semiconductor chip, wherein a surface area of the depression is at least a size of a surface area of the second surface of the semiconductor chip and is less than a surface area of the first surface of the substrate.

In one embodiment, a package on package semiconductor package (PoP) comprises a first substrate, the first substrate comprising a first surface, a second surface opposite the first surface, a redistribution layer comprising a plurality of rerouting lines, a plurality of first through substrate vias (TSVs), and a plurality of second TSVs, wherein the second surface comprises a cavity formed therein at a center of the second surface; a plurality of first conductive terminals disposed at the first surface; a semiconductor chip disposed at the cavity, the semiconductor chip comprising a first surface and a second surface opposite the first surface, wherein the first surface of the semiconductor chip opposes the second surface of the first substrate; a first semiconductor package electrically connected to the first substrate, the first semiconductor package comprising a second substrate, the second substrate having a first surface and a second surface, wherein the first surface of the second substrate opposes the second surface of the semiconductor chip, and wherein an aspect ratio of the plurality of the first TSVs is at least 10:1 and an aspect ratio of the second TSVs is at least the same or greater than an aspect ratio of the plurality of first TSVs.

### BRIEF DESCRIPTION OF THE DRAWINGS

The above and other aspects and features of the disclosure will become apparent by describing in detail exemplary embodiments thereof with reference to the attached drawings, in which:

FIG. 1 is a cross-sectional view of a package on package (PoP) employing a through substrate via (TSV) technique, according to one embodiment;

FIG. 2 is a plan view of a re-distribution layer (RDL) in which TSVs formed in an interposer of the PoP of FIG. 1 are connected via routing lines, according to one embodiment;

FIG. 3 is a cross-sectional view of a PoP employing the TSV technique, according to one embodiment;

FIG. 4 is a plan view of an RDL in which TSVs formed in an interposer of the PoP of FIG. 3 are connected via routing lines, according to one embodiment;

FIG. 5 a cross-sectional view of a PoP employing the TSV technique, according to one embodiment;

FIG. 6 is a plan view of an RDL in which TSVs formed in a substrate of a lower semiconductor package of the PoP of FIG. 5 are connected via routing lines, according to one embodiment;

FIG. 7 is a base plan view of an RDL in which TSVs formed in a substrate of a lower semiconductor package of the PoP of FIG. 5 are connected to lower conductive terminals via routing lines, according to one embodiment;

FIG. 8 a cross-sectional view of a PoP employing the TSV technique, according to one embodiment; and

FIG. 9 is a plan view of an RDL in which TSVs formed in a substrate of a lower semiconductor package of the PoP of FIG. 8 are connected via routing lines, according to one embodiment.

### DETAILED DESCRIPTION OF THE EMBODIMENTS

Various example embodiments will now be described more fully hereinafter with reference to the accompanying drawings, in which exemplary embodiments are shown. The present invention may, however, be embodied in many different forms and should not be construed as limited to the example embodiments set forth herein. That is, these example embodiments are just that—examples—and many implementations and variations are possible that do not require the various details herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention. In the drawings, the sizes and relative size of layers and regions may be exaggerated for clarity. Like numerals refer to like elements throughout.

The terminology used herein is for the purpose of describing particular embodiments only and is not intended to limit the invention. As used herein, the singular terms “a,” “an” and “the” should not exclude the plural forms as well, unless the context clearly indicates otherwise. As used herein, the term “and/or” includes any and all combinations of one or more of the associated listed items. It will be understood that when an element or a layer is referred to as being “on,” “connected to” or “coupled to” another element or layer, it may be directly on, connected to, or coupled to the other element or layer or intervening elements or layers may be present. In contrast, when an element is referred to as being “directly on,” “directly connected to” or “directly coupled to” another element or layer, there are no intervening elements or layers present. Other words used to describe the relationship between elements or layers should be interpreted in a like fashion (e.g., “between” versus “directly between;” “adjacent” versus “directly adjacent,” etc.).

It will be further understood that the terms “comprises”, “comprising,” “includes” and/or “including”, when used herein, specify the presence of stated features, integers, steps, operations, elements, and/or components, but do not preclude the presence or addition of one or more other features, integers, steps, operations, elements, components, and/or groups thereof.

Terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes.

Example embodiments are described herein with reference to cross-sectional illustrations that are schematic illustrations of idealized example embodiments (and intermediate structures) of example embodiments. As such, variations from the shapes of the illustrations as a result, for example, of manufacturing techniques and/or tolerances, are to be expected. Example embodiments should not be construed as limited to those shown in the views, but include modifications in configuration formed on the basis of, for example, manufacturing processes. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures may be schematic in nature and their shapes are not intended to limit the scope of the present disclosure.

It will be also understood that although the terms first, second, third etc. may be used herein to describe various elements, components, regions, layers and/or sections, these elements, components, regions, layers, and/or sections should not be limited by these terms. Unless otherwise indicated, these terms are only used to distinguish one element, component, region, layer, or section from another element, components, region, layer, or section. Thus, a first element, components, region, layer, or section in some embodiments could be termed a second element, components, region, layer, or section in other embodiments, and, similarly, a second element, components, region, layer, or section could be termed a first element, components, region, layer, or section without departing from the teachings of the disclosure. Exemplary embodiments explained and illustrated herein may include their complementary counterparts.

Locational terms, such as “beneath,” “below,” “lower,” “above,” “upper” and the like, may be used herein for ease of description to describe one element or feature's relationship to another element(s) or feature(s) as illustrated in the figures. It will be understood that the locational terms may be relative to a device and are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the locational descriptors used herein interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present application and will not be interpreted in an idealized or overly formal sense unless expressly so defined herein.

Hereinafter, example embodiments will be explained in detail with reference to the accompanying drawings.

The present disclosure relates to a semiconductor device including through substrate vias (TSVs), and more particularly, to a package on package (PoP) including an upper semiconductor package and a lower semiconductor package connected by using TSVs. The TSVs disclosed herein may be through silicon vias or may be through vias formed in materials other than silicon, such as other types of insulative or semiconductive material suitable for use for a conductive via.

There have been various technical attempts to improve the integration degree of a semiconductor device and diversify functions of the semiconductor chip by using various manufacturing packaging techniques.

FIG. 1 is a cross-sectional view of a package on package (PoP) 500 employing a through substrate via (TSV) technique, according to some embodiments.

Referring to FIG. 1, the PoP 500 includes a lower semiconductor package 100, an interposer 200 having TSVs, and an upper semiconductor package 300.

In the lower semiconductor package 100, first conductive terminals 106, such as solder balls, conductive plugs, etc., may be attached to a lower part of a substrate 102. The first conductive terminals 106 may connect the PoP 500 with a main printed circuit board of an electronic device, and the first conductive terminals 106 may be embodied as solder land type conductive terminals. The interposer 200 may be used to connect the upper semiconductor package 300 and the lower semiconductor package 100. The interposer 200 may be used instead of conventional conductive terminals, such as solder balls of a large diameter.

The interposer 200 may be formed to comprise a first portion 230 and a second portion 240 disposed on horizontal ends of an upper surface of the first portion 230. In some embodiments, the interposer 200 may be a single piece formed by etching, CMP, or other methods, with the first portion 230 and the second portion 240 indicative of specific areas or sections of the interposer 200. In other embodiments, the interposer 200 may be formed with multiple parts, and the first portion 230 and second portion 240 may be indicative of those parts, or may be indicative of specific areas or sections of the interposer 200 as a whole. The surface area of each of the upper and lower surfaces of the first portion 230 may be equivalent or may be smaller than a surface area of the upper surface of the lower substrate 102. For example, the upper and lower surfaces of the first portion 230 may have a same or similar width, length, and depth as the upper surface of the lower substrate 102. The lower surface B of the first portion 230 may face the upper surface of the lower substrate 102 and may be parallel or substantially parallel to the upper surface of the lower substrate 102.

The second portion 240 comprises two upward protrusions of the interposer 200, each disposed at horizontal or lateral ends of the upper surface of the first portion 230. In some embodiments, the entire bottom surface of the second portion 240 (which includes the bottom surfaces of both protrusions) is in contact with the upper surface of the first portion 230. The upper surface T of the second portion 240 (which includes the upper surfaces of both protrusions) may or may not extend in an inward lateral direction as far as the bottom surface of the second portion 240. For example, the side of the second portion 240 that faces inward in the PoP 500 may have a vertical slope (e.g. may be perpendicular or substantially perpendicular to the opposite side of the second portion 240) or may have a positive or negative slope. In other examples, the side of the second portion 240 that faces inward in the PoP 500 may be perpendicular to the upper surface of the first portion 230. In some embodiments, the side of the second portion 240 that faces inward in the PoP 500 may not be completely straight.

In some embodiments, the upper surface of the first portion 230 may have a length that is three times as long as the bottom surface of the second portion 240. In some embodiments, the length of the upper surface of the first portion 230 may range from being 1.5 to 5 times as long as the length of the bottom surface of the second portion 240. The length of the upper surface of the first portion 230 that remains exposed (i.e. that is not contacted by the bottom surface of the second portion 240) may be large enough to hold a semiconductor chip. In some embodiments, the exposed portion of the upper surface of the first portion 230 may range from 1.2 to 1.5 times the length of a semiconductor chip. This exposed portion of the upper surface of the first portion 230 may also be considered to be a recessed space 218, in which a semiconductor chip may be disposed. The recessed space 218 may be, for example, a cavity or a depression disposed at the upper surface of the first portion 230. The height of the recessed space 218, or the height into which the recessed space 218 extends into the interposer 200 may be similar to the height of a semiconductor chip. For example, the height may range from 0.5-1.5 times the height of a semiconductor chip (i.e. semiconductor chip 104). The surface area of the recessed space 218 may at least be the surface area of a bottom surface of a semiconductor chip (i.e. semiconductor chip 104). The surface area of the recessed space 218 may be less than the surface area of the lower or upper surface of the first portion 230.

In some embodiments, the second portion 240 is disposed beneath the first portion 230, such that the second portion 240 is flipped upside down. In these embodiments, the entire upper surface of the second portion 240 is in contact with the bottom surface of the first portion 230, and the bottom surface of the second portion 240 may not extend as far in a lateral inward direction as the upper surface of the second portion 240. As mentioned above, the structure of the interposer 200 (with the first portion 230 and the second portion 240) allows for a recessed space 218, in which a semiconductor chip may be disposed.

TSVs 212 and 214 may be formed in the interposer 200 in order to form fine-pitch vertical connection terminals of the PoP 500. The TSVs 212 and 214 may have pitches of a width of 200 μm or less. A higher number of the vertical connection terminals per unit area may be formed in the PoP 500 by forming TSVs 212 and 214. For example, the vertical connection terminals with fine pitches may reduce a superficial area of the PoP 500. In some embodiments, the TSVs 214 may have a higher aspect ratio than the TSVs 212. In the present disclosure, the TSVs 212 and/or 214 may be used, for example, as signal lines to interconnect the upper semiconductor package 300 and the lower semiconductor package 100.

In some embodiments, the TSVs 212 may be formed solely in a first portion 230 of the interposer. In some embodiments, the TSVs 212 may extend from (or past) an external surface of the first portion 230. In some embodiments, the TSVs 212 may extend from (or past) a bottom surface of the first portion 230. In some embodiments, the TSVs 214 may be formed in both the first portion 230 and the second portion 240 of the interposer, extending from the first portion 230 to the second portion 240. In some embodiments, the TSVs 214 may extend from (or past) an external surface of the first portion 230. In some embodiments, the TSVs 214 may extend from (or past) an external surface of the second portion 240. In some embodiments, the TSVs 214 may include a first TSV formed in the first portion 230 and a second TSV formed in the second portion 240, where the first TSV and the second TSV are stacked together.

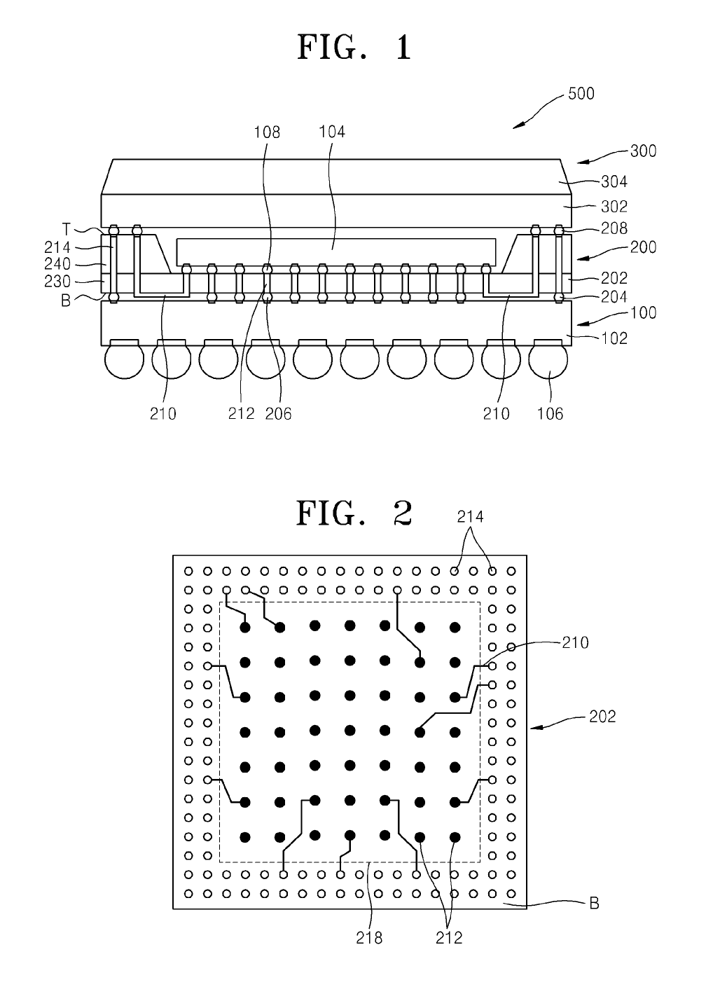

In the interposer 200, routing lines 210 for re-distributing the TSVs 212 and 214 may be included in a re-distribution line (RDL) layer 202. In some embodiments, and as shown in FIG. 2, the RDL 202 is disposed at the first portion 230. In some embodiments, the RDL 202 is separate from the first portion 230 but is still part of the interposer 200. Re-distribution of vertical connection terminals may be done on a substrate of an upper or lower semiconductor package. In the interposer 200, according to some embodiments, the re-distribution is set forth in the interposer 200, which connects the upper semiconductor package 300 and the lower semiconductor package 100. In these embodiments, a redistribution layer to re-distribute the TSVs 212 and 214 does not need to be formed in the substrate 302 of the upper semiconductor package 300 and/or the substrate 102 of the lower semiconductor package 100. In these embodiments, an overall thickness of the substrates 102 and/or 302 may be reduced, thereby reducing a height of the PoP 500.

As discussed above, the interposer 200 may have a recessed space 218 for accommodating a semiconductor chip, for example semiconductor chip 104 of the lower semiconductor package 100. In some embodiments, the recessed space 218 may be formed in a middle of an upper surface of the interposer 200. In other embodiments, the recessed space 218 may be formed in a middle of a lower surface of the interposer 200. The semiconductor chip 104 of the lower semiconductor package 100 may be disposed on bumps 108 in the recessed space 218. The bumps 108 may be electrically connected to the substrate 102 of the lower semiconductor package 100 by being electrically interconnected with the TSVs 212 in the interposer 200. In some embodiments, signals, power, and/or logical communication may be transmitted from the lower semiconductor package 100 through the TSVs 212 and the bumps 108 to the semiconductor chip 104.

In some embodiments, the interposer 200 may be formed of a semiconductor, such as silicon (which may be crystalline silicon), glass, or some other such substrate (e.g., silicon on insulator, which may be amorphous, polycrystalline or crystalline silicon formed on glass), based on a wafer manufacturing method used. The interposer 200 may comprise a wafer amenable to standard semiconductor manufacturing processes. For example, the interposer 200 may be formed from a 200 mm (8 inch), 300 mm (12 inch) or 450 mm (18 inch) wafer. In other embodiments, the interposer 200 may be formed by using glass, a rigid printed circuit board (PCB) like FR4, or a flexible PCB like polyimide (PI). Alternatively, or in addition, the interposer 200 may be formed from a rigid material, having a Young's modulus of 100 GPa or more. A top surface of the interposer 200 may have a smooth and/or flat surface. As one example, the rms (root mean square) surface roughness of the interposer 200 may be 1.5 nm or less. In some embodiments, a region where the RDL 202 of the interposer 200 is formed may be made of a flexible PCB or a rigid PCB, and a region of the interposer 200 where the TSVs 214 with a large aspect ratio are formed may be made of silicon or glass.

In some embodiments, the interposer 200 may further include second conductive terminals 204 and 206 for connecting the TSVs 214 and 212 at the lower surface of the interposer 200 to the substrate 102 of the lower semiconductor package 100. The interposer 200 may also include third conductive terminals 208 for connecting the TSVs 214 at the upper surface of the interposer 200 to the substrate 302 of the upper semiconductor package 300. The second conductive terminals 204 and 206 and the third conductive terminals 208 may be solder balls, conductive plugs, etc. In some embodiments, the second conductive terminals 204 and 206 and the third conductive terminals 208 may be formed in a solder bump shape or a solder land shape, rather than a solder ball shape, in order to conveniently realize fine-pitch vertical connection terminals.

In some embodiments, the bumps 108, second conductive terminals 204, and/or third conductive terminals 208 may have a height of about 30 μm or less, or a height of 20 μm or less. In some embodiments, a height from a bottom surface of the interposer 200 to the upper surface of the lower package 200 may be about 0.13 mm or less, or 0.12 mm or less. In some embodiments, TSVs 212 and 214 may be made using wafer level processes (such as photolithographic processes), with fine wiring sizes. For example, a wiring pitch of the RDL 202 may be 10 μm or less, or 5 μm or less.

In some embodiments, the semiconductor chip 104 may have endured backside grinding, which may also reduce the overall height of the package. When the interposer 200 is formed of a material having a CTE (coefficient of thermal expansion) the same as or close to that of the semiconductor chip 104, the semiconductor chip 104 can be made even thinner with minimal concern to subsequent cracking due to a CTE mismatch. For example, the CTE of interposer 200 and semiconductor chip 104 may both be less than 6 ppm/K, or less than 4 ppm/K. In some embodiments, the CTE of the interposer 200 may be no greater than twice the CTE of the semiconductor chip 104. In some embodiments, the CTE of the interposer 200 may be no greater than about 1.3 times the CTE of the semiconductor chip 104. In some embodiments, the interposer 200 and the semiconductor chip 104 may have substantially the same CTE (e.g., they may be formed from the same materials).

In some embodiments, when the interposer 200 is formed of a material having a CTE the same as or close to that of the semiconductor chip 104, second conductive terminals 206 and/or third conductive terminals 208 may be made smaller with minimal risk of damage (e.g., cracking or detaching). For example, the second conductive terminals 206 and/or third conductive terminals 208 may have a height of 20 μm or less.

In embodiments in which the PoP 500 is a semiconductor device used in a mobile phone, the lower semiconductor package 100 may be a logic device such as a processor and the upper semiconductor package 300 may be a memory device. In these embodiments, the upper semiconductor package 300 may be a multi-chip package including a plurality of stacked semiconductor chips (not shown), and the upper surface of the substrate 302 of the upper semiconductor package 300 may be sealed with an encapsulant 304 to protect the plurality of stacked semiconductor chips.

FIG. 2 is a plan view of the RDL 202 in which the TSVs 212 and 214 formed in an interposer 200 of the exemplary PoP 500 of FIG. 1 are connected via the routing lines 210.

Referring to FIG. 2, in the interposer 200, the TSVs 214 with a large aspect ratio are formed in the edges of the RDL 202, and the TSVs 212 with a small aspect ratio are connected with the bumps 108 (of FIG. 1) of the lower semiconductor chip 104 (of FIG. 1) and are formed at the middle of the RDL 202. For example, as mentioned above, the TSVs 212 may be formed in only the first portion 230 of the interposer 200, while the TSVs 214 may be formed to extend from the first portion 230 to the second portion 240 of the interposer 200. In some embodiments, the TSVs 212 may be formed at a recess (i.e. a section including the exposed portion of the upper surface of the first portion 230) of the interposer 200 in which the second portion 240 of the interposer is not formed. In some embodiments, vertical connection terminals connecting an upper semiconductor package and a lower semiconductor package may be formed in the interposer 200 having TSVs. In other embodiments, the TSVs 212 and TSVs 214 may extend to or past the external surfaces of the interposer 200 to contact terminals and/or bumps electrically connected to other parts of the PoP 500.

In some embodiments, in the interposer 200, the routing lines 210 that interconnect the TSVs 212 and 214 in the RDL 202 are separately prepared. In some embodiments, the routing lines 210 may be prepared at the same time. Only a part of the routing lines 210 is illustrated in the drawing. The form of the routing lines 210 may change depending on the types and functions of the PoP and the semiconductor chips contained therein. In some embodiments, a RDL formed on the substrate 102 of the lower semiconductor package in the PoP 500 is unnecessary, and an overall thickness of the substrate 102 may be reduced and an overall height of the PoP 500 may also be reduced. The path of a signal transferred from the semiconductor chip 104 of the lower semiconductor package 100 may also be reduced, and the operational speed of the semiconductor device may be increased. Reference numeral 218 in FIG. 2 denotes the recessed space provided by the structure of the interposer 200 for loading the semiconductor chip 104 of the lower semiconductor package 100.

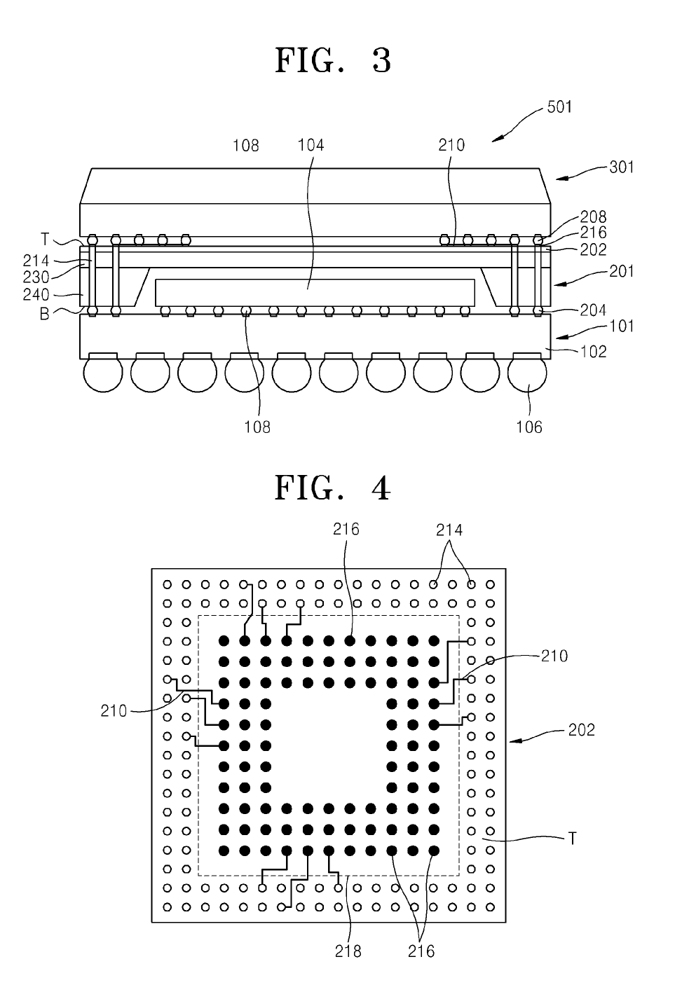

FIG. 3 is a cross-sectional view of a PoP 501 employing the TSV technique, according to one embodiment.

Referring to FIG. 3, the PoP 501 includes a lower semiconductor package 101, an interposer 201 having TSVs disposed therein, and an upper semiconductor package 301.

In some embodiments, a recessed space 218 for accommodating a semiconductor chip 104 of the lower semiconductor package 101 is prepared in a middle of a lower surface of the interposer 201 of the PoP 501 of FIG. 3. The interposer 201 may be the same or similar to the interposer 200. For example, the interposer 201 may also be formed with a first portion 230 and a second portion 240. In the interposer 201, the second portion 240 is disposed beneath the first portion 230. In these embodiments, the semiconductor chip 104 of the lower semiconductor package 101 may be disposed on a substrate 102 of the lower semiconductor package 101. The semiconductor chip 104 may be disposed at the recessed space of the interposer 201 and connected to the lower semiconductor package substrate 102 via bumps 108.

In some embodiments, inside the interposer 201, the TSVs 214 with large aspect ratios are formed, but TSVs with small aspect ratios are not formed. In some of these embodiments, the TSVs 214 may extend throughout the interposer 201, for example, extending through only the first portion 230 and through both the first portion 230 and the second portion 240 of the interposer 201. The TSVs 214 may have an aspect ratio of 10:1 or higher, and a pitch between the TSVs 214 may be 200 μm or less. In these embodiments, a number of vertical connection terminals that may be formed per unit area in the PoP 501 may be increased, and a superficial area of the PoP 501 may be reduced.

In some embodiments, the interposer 201 may include routing lines 210 that re-distribute the TSVs 214, in a RDL 202. An exemplary flat structure of the routing lines 210 will be described more fully with reference to FIG. 4 below. In these embodiments, the routing lines 210 are disposed in the interposer 201. Accordingly, at least one RDL does not need to be formed in a substrate of the upper semiconductor package 300 and/or the lower semiconductor package 100 in order to re-distribute the TSVs 214. An overall thickness of the substrates 102 and/or 302 may be reduced, thereby reducing a height of the PoP 501.

The interposer 201 may be formed of silicon, based on a wafer manufacturing method used. In some embodiments, a region where the RDL 202 of the interposer 201 is formed may be made of a flexible PCB or a rigid PCB, and a region of the interposer 201 where the TSVs 214 with a large aspect ratio are formed may be made of silicon or glass. The interposer 201 and RDL 202 may also be formed of the same or similar materials as the interposer 200 and the RDL 202 discussed with respect to PoP 500.

The interposer 201 may further include second conductive terminals 204 on a lower surface B of the second portion 240 of the interposer 201 for connecting the TSVs 214 and a substrate 102 of the lower semiconductor package 101, and third conductive terminals 208 on an upper surface T of the first portion 230 of the interposer 201 for connecting the TSVs 214 and a substrate of the upper semiconductor package 301. The second conductive terminals 204 and the third conductive terminals 208 may be solder balls, conductive plugs, etc. In some embodiments, the second conductive terminals 204 and the third conductive terminals 208 may be formed in a solder bump shape or a solder land shape, rather than a solder ball shape, in order to conveniently realize fine-pitch vertical connection terminals.

FIG. 4 is a plan view of the RDL 202 in which TSVs 214 formed in an interposer 201 of an exemplary PoP 501 of FIG. 3 are connected via routing lines 210.

Referring to FIG. 4, in some embodiments, the RDL 202 may be formed at an upper surface T of the first portion 230 of the interposer 201. In other embodiments, the RDL 202 may be separate from the first portion 230 of the interposer 230, but may still be formed as a part of the interposer 201. The TSVs 214 with a large aspect ratio may be formed in the edges of the interposer 201. In some embodiments, the TSVs 214 are formed in a section of the interposer in which both the first and second portions 230, 240 are formed. As mentioned above, the TSVs 214 may extend from the first portion 230 to the second portion 240 and may extend to, at, or past the external surfaces of the first and second portions 230, 240.

Routing conductive terminals 216 may also be formed in a middle of the RDL 202. In some embodiments, one end of a routing conductive terminal 216 is connected to a respective TSV 214 via a routing line 210 and another end is connected to the substrate of the upper semiconductor package 301 (of FIG. 3). The routing conductive terminals 216 prepared at the middle of the RDL 202 enable superficial expansion of the region where the vertical connection terminals are formed, via the routing lines 210, when the lower semiconductor package 101 and the upper semiconductor package 301 are electronically connected.

Vertical connection terminals connecting an upper semiconductor package and a lower semiconductor package may exist in the interposer 201. In the interposer 201, according to some embodiments, the routing lines 210 that superficially interconnect the TSVs 214 in the RDL 202 may be separately prepared. In other embodiments, the routing lines 210 may be prepared at a same time. Only a part of the routing lines 210 is illustrated in the drawing. The form of the routing lines 210 may change depending on the types and functions of the PoP and the semiconductor chips contained therein. The spacing of the TSVs 212 and 214 may also change depending upon the type and function of the PoP 502 and the semiconductor chips contained therein. For example, in the RDL 202, the TSVs 212 may be spaced evenly in the recessed space 218A. The recessed space 218A may be the same or similar to the recessed space 218. Even spacing may be used in the RDL 202 since it is disposed in the interposer, which may not contain any circuitry or structure to obstruct the even spacing of the TSVs 212.

In some embodiments, a RDL formed on the substrate of the upper semiconductor package 301 in the PoP 501 is unnecessary, and an overall thickness of the substrates 102 and/or 302 may be reduced, and therefore, an overall height of the PoP 501 may also be reduced.

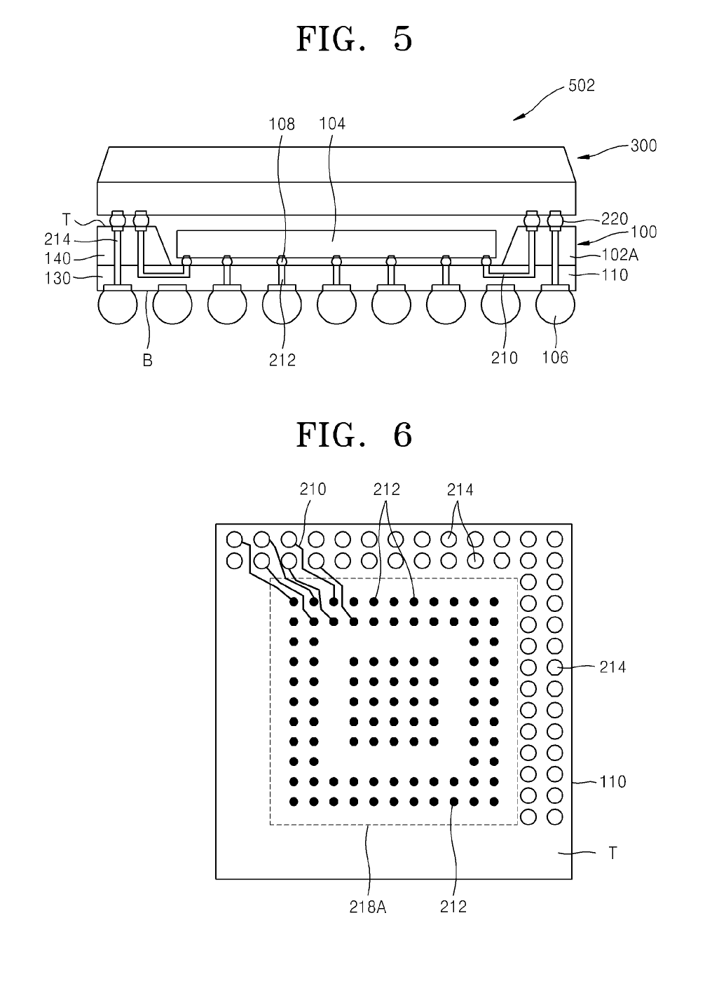

FIG. 5 a cross-sectional view of a PoP 502 employing the TSV technique according to another embodiment.

Referring to FIG. 5, a PoP 502 may use a TSV technique according to some embodiments. The PoP 502 may include a lower semiconductor package 100 having first conductive terminals 106 disposed on a lower surface thereof, and an upper semiconductor package 300 disposed above the lower semiconductor package 100, where the upper semiconductor package 300 is to be electronically connected to the lower semiconductor package 100. A substrate 102A of the lower semiconductor package 100 has a recessed space 218A to accommodate a semiconductor chip 104 of the lower semiconductor package 100 on an upper surface T of the substrate 102A. The substrate 102A of the lower semiconductor package 100 may include TSVs 214 and 212 that provide vertical electrical connections and may have routing lines 210 disposed therein for re-distributing the TSVs 214 and 212.

In these embodiments, the function of the interposers 200 and 201 described, for example, with regard to FIG. 1 and FIG. 3 is carried out by the substrate 102A of the lower semiconductor package 100. In some embodiments, the substrate 102A may be a single piece formed by etching, CMP, or other methods, with a first portion 130 and a second portion 140 indicative of specific areas or sections of the substrate 102A. In other embodiments, the substrate 102A may be formed with multiple parts, and a first portion 130 and a second portion 140 may be indicative of those parts, or may be indicative of specific areas or sections of the substrate 102A as a whole. The first portion 130 and the second portion 140 of the substrate 102A may be the same or similar to the first portion 230 and the second portion 240 of the interposer 200 with regard to size, shape, and relative disposition. In some embodiments, TSVs 212 may be disposed only in the first portion 130, while TSVs 214 may extend from the first portion 130 to the second portion 140 in a manner similar to the TSVs 214 in the interposer 200. The first portion 130 and second portion 140 of the substrate 102A may also contain the structure and functionality of the substrate 102 of the lower semiconductor package 100 of PoP 500. For example, the substrate 102A may also contain the same or similar circuitry, vias, etc., as the substrate 102.

In some embodiments, some of the TSVs 214 may extend from the second portion 140 to the first portion 130 and connect to lower conductive terminals 106, and some of the TSVs 214 may extend from the second portion 140 to the first portion 130 and connect to routing lines 210 disposed in the first portion 130 of the substrate 102A. In some embodiments, some of the TSVs 212 may extend from the first portion 130 and connect to lower conductive terminals 106, and some of the TSVs 212 may extend from the first portion 130 and connect to routing lines 210 disposed in the first portion 130 of the substrate 102A.

In some embodiments, the substrate 102A of the lower semiconductor package 100 may have a recessed space, for example recessed space 218, in which the semiconductor chip 104 is disposed. The recessed space may be formed at a middle of an upper surface T of the second portion 140 of the substrate 102A, and the semiconductor chip 104 may be disposed at the recessed space of the substrate 102A (i.e. a section of the upper surface T of the substrate 102A in which the second portion 140 is not formed). The semiconductor chip 104 may be disposed on bumps 108 at an upper surface of the first portion 130. The bumps 108 may be electronically connected to the TSVs 212 with a low aspect ratio in the substrate 102A of the lower semiconductor package 100.

The PoP 502 includes fourth conductive terminals 220 electronically connecting the TSVs 214 of the lower semiconductor package 100 to a substrate of the upper semiconductor package 300. The fourth conductive terminals 220 may be solder balls, conductive plugs, etc. For example, the fourth conductive terminals 220 may be formed in a solder bump shape or a solder land shape, rather than a solder ball shape, in order to conveniently realize fine-pitch vertical connection terminals in the PoP 502.

An overall size of the PoP 502 may be reduced and a number of vertical connection terminals disposed in the substrate 102A may be increased due to the TSVs 214 and 212 prepared in the substrate 102A of the lower semiconductor package 100 and the structure of a RDL 110, in which the routing lines 210 are formed to enable a superficial expansion of the TSVs 214 and 212.

FIG. 6 is an exemplary plan view of the RDL 110 in which the TSVs 214 and 212 formed in the substrate 102A of the lower semiconductor package 100 of the exemplary PoP 502 of FIG. 5 are connected via the routing lines 210.

Referring to FIG. 6, the TSVs 214 with a large aspect ratio are formed at the edges of the RDL 110, and the TSVs 212 with a small aspect ratio are formed at the middle of the upper surface T of the RDL 110 where the semiconductor chip 104 (of FIG. 5) is disposed. In the RDL 110, the TSVs 214 and 212 with different aspect ratios may be interconnected by the routing lines 210. Only a part of the routing lines 210 is illustrated in the drawing. In some embodiments, the form of the routing signal lines 210 may change depending on the types and functions of the PoP 502 and the semiconductor chips contained therein. The spacing of the TSVs 212 and 214 may also change depending upon the type and function of the PoP 502 and the semiconductor chips contained therein. For example, in the RDL 110, TSVs 212 may not be spaced evenly in the recessed space 218A. In some examples, the TSVs 212 are spaced at a periphery and a center of the recessed space 218A. This may be done to accommodate the circuitry or other structures present in the substrate 102A of the lower semiconductor package 100 or for other reasons. Reference numeral 218A in FIG. 6 denotes the recessed space for loading a semiconductor chip, for example, the semiconductor chip 104 of the lower semiconductor package 100.

FIG. 7 is an exemplary base plan view of the RDL 110 in which some of the TSVs 212 and 214 formed in the substrate 102A of the lower semiconductor package 100 of the PoP 502 of FIG. 5 are connected to lower conductive terminals 106 (of FIG. 5) either directly or via the routing lines 210. In some embodiments, the TSVs 212 are formed at the middle of a lower surface B of the RDL 110 and connected to the bumps 108 of the semiconductor chip 104 (of FIG. 5) of the lower semiconductor package 100. For example, the TSVs 212 are formed at a section of the substrate 102A in which only the first portion 130 is formed. Some of the TSVs 214 are connected to the first conductive terminals 106 (of FIG. 5) of the lower semiconductor package 100 via, for example, the routing lines 210. In some embodiments, some of the TSVs 212 are also connected to the first conductive terminals 106 of the lower semiconductor package 100 by, for example, the routing lines 210. By superficially connecting the TSVs 214 and 212 with an aspect ratio of 10:1 or higher and a pitch between the TSVs 214 and 212 of 200 μm or less, the overall size of the PoP 502 may be reduced, and the number of vertical connection terminals may be increased.

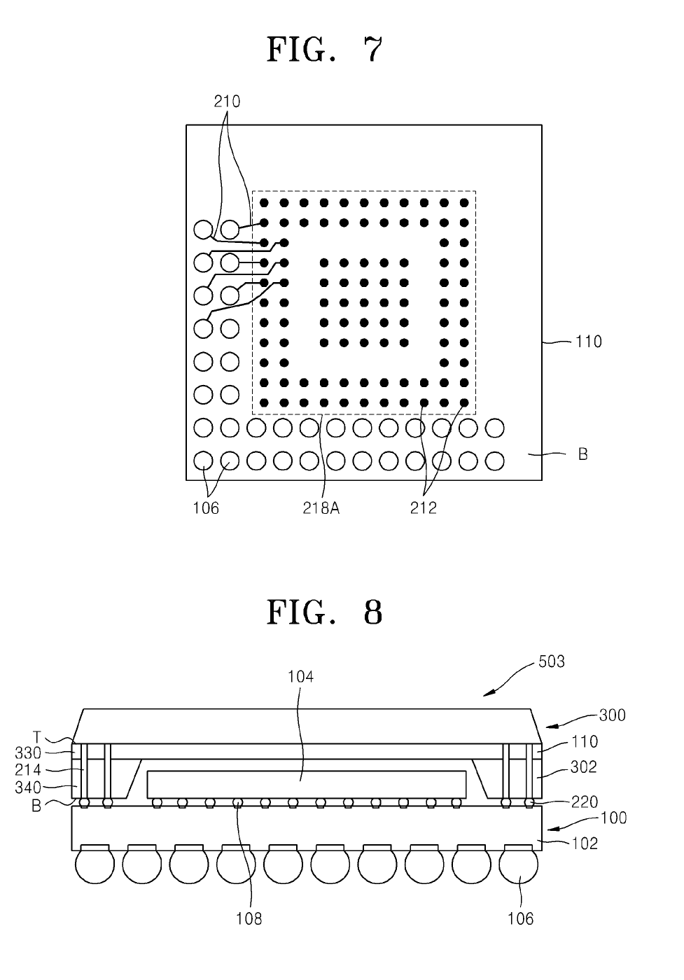

FIG. 8 a cross-sectional view of a PoP 503 employing the TSV technique according to another embodiment.

Referring to FIG. 8, a PoP 503 may use a TSV technique according to another embodiment. The PoP 503 include a lower semiconductor package 100 having a plurality of first conductive terminals 106 disposed on a lower part thereof; and an upper semiconductor package 300 disposed above the lower semiconductor package 100 to be electronically connected to the lower semiconductor package 100. In some embodiments, a substrate 302 may be a single piece formed by etching, CMP, or other methods, with a first portion 330 and a second portion 340 indicative of specific areas or sections of the substrate 302. In other embodiments, the substrate 302 may be formed with multiple parts, and a first portion 330 and a second portion 340 may be indicative of those parts, or may be indicative of specific areas or sections of the substrate 302 as a whole. The substrate 302 may be similar or the same to the substrate 102A. For example, the first portion 330 and the second portion 340 of the substrate 302 may be the same or similar to the first portion 130 and the second portion 140 of the interposer 200 with regard to size, shape, and relative disposition, but may not include TSVs 212. For example, TSVs 214 may extend from the first portion 330 to the second portion 340 in a manner similar to the TSVs 214 in the interposer 200. The first portion 330 and second portion 340 of the substrate 302 may also contain the structure and functionality of the substrate 302 of the upper semiconductor package 300 of PoP 500. For example, the substrate 300 may contain the same or similar circuitry, vias, etc., as the substrate 302.

The structure of substrate 302 of the upper semiconductor package 300 allows for a recessed space (e.g. recessed space 218) to accommodate a semiconductor chip 104 of the lower semiconductor package 100. The recessed space 218 of the substrate 302 may be the same or similar to the recessed space 218 of the interposer 200. The semiconductor chip 104 may be disposed at the lower surface B (e.g. the lower surface of the second portion 340) of the substrate 302. The substrate 302 of the upper semiconductor package 300 may include connections and routing lines 210 for re-distributing the TSVs 214 in a RDL 110.

In these embodiments, the function of the interposers 200 and 201 described, for example, with regard to FIG. 1 and FIG. 3 is carried out by the substrate 302 of the upper semiconductor package 300. As mentioned above, the substrate 302 of the upper semiconductor package 300 may have the recessed space for accommodating the semiconductor chip 104.

In some embodiments, the PoP 503 includes a plurality of fourth conductive terminals 220 electronically connecting the TSVs 214 of the upper semiconductor package 300 to the substrate 102 of the lower semiconductor package 100. The fourth conductive terminals 220 may be solder balls, conductive plugs, etc. For example, the fourth conductive terminals 220 may be formed in a solder bump shape or a solder land shape, rather than a solder ball shape, in order to conveniently realize fine-pitch vertical connection terminals in the PoP 503.

An overall size of the PoP 503 may be reduced and a number of vertical connection terminals may be increased due to the TSVs 214 prepared in the substrate 302 of the upper semiconductor package 300 and the structure of a RDL 110, in which the routing lines 210 are formed enabling a superficial expansion of the TSVs 214.

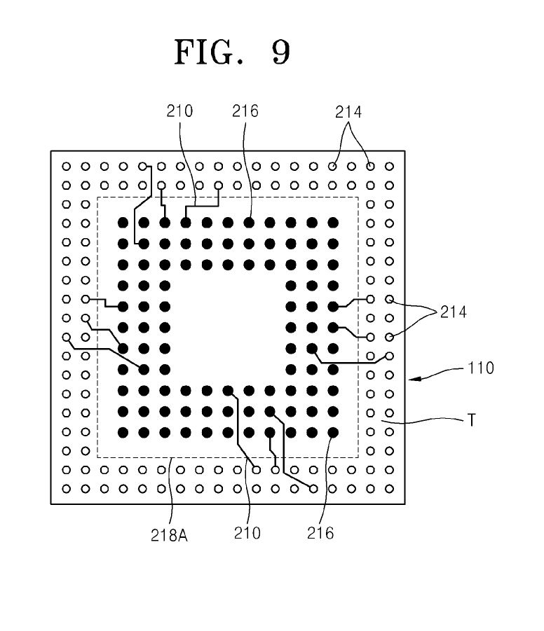

FIG. 9 is a plan view of the RDL 110 in which the TSVs 214 formed in the substrate 302 of the upper semiconductor package 300 of the PoP 503 of FIG. 8 are connected via the routing lines 210.

Referring to FIG. 9, the TSVs 214 with a large aspect ratio are formed at the edges of the RDL 110, and the routing conductive terminals 216 are formed at a middle of the RDL 110. The routing conductive terminals 216 are connected to the TSVs 214 via the routing lines 210 and are connected to a semiconductor chip (not shown) of the upper semiconductor package 300 (of FIG. 8). The routing conductive terminals 216 prepared at the middle of the RDL 202 enable superficial expansion of the region where the vertical connection terminals are formed, via the routing lines 210 when the lower semiconductor package 100 and the upper semiconductor package 300 are electronically connected. Only a part of the routing signal lines 210 is illustrated in the drawing. The form of the routing signal line 210 may change depending on the types and functions of the PoP 503 and the semiconductor chips contained therein. In some embodiments, the form of the routing signal lines 210 may change depending on the types and functions of the PoP 502 and the semiconductor chips contained therein. The spacing of the TSVs 214 and routing conductive terminals 216 may also change depending upon the type and function of the PoP 502 and the semiconductor chips contained therein. For example, in the RDL 110, routing conductive terminals 216 may not be spaced evenly in the recessed space 218A. In some examples, the routing conductive terminals 216 are spaced at a periphery and a center of the recessed space 218A. This may be done to accommodate the circuitry or other structures present in the substrate 302 of the lower semiconductor package 100 or for other reasons. Reference numeral 218A in FIG. 9 denotes the recessed space for loading the semiconductor chip 104 of the lower semiconductor package 100.

The above-disclosed subject matter is to be considered illustrative and not restrictive, and the appended claims are intended to cover all such modifications, enhancements, and other embodiments, which fall within the true spirit and scope of the disclosed embodiments. Thus, the invention is to be construed by the broadest permissible interpretation of the following claims and their equivalents, and shall not be restricted or limited by the foregoing detailed description.

What is claimed is:

1. A package on package semiconductor package (PoP), the PoP comprising:
a first substrate, the first substrate having a first surface, a second surface opposite the first surface, and a redistribution layer comprising a plurality of rerouting lines;
a plurality of first conductive terminals disposed at the first surface;
a recess disposed at the second surface;
a semiconductor chip disposed at the recess, the semiconductor chip comprising a first surface and a second surface opposite the first surface, wherein the first surface of the semiconductor chip opposes the second surface of the first substrate; and
a first semiconductor package electrically connected to the first substrate, the first semiconductor package comprising a second substrate, the second substrate having a first surface and a second surface,
wherein the first surface of the second substrate opposes the second surface of the semiconductor chip, and
wherein a height of the recess is at least 50% of a height of the semiconductor chip.

2. The PoP of claim 1, wherein the first substrate comprises a plurality of first through substrate vias (TSVs) extending therethrough, a first end of each of the first TSVs disposed at a portion of the second surface comprising the recess.

3. The PoP of claim 2, wherein one or more of the first TSVs comprises a second end physically connected to a respective one of the plurality of routing lines of the redistribution layer.

4. The PoP of claim 2, wherein one or more of the first TSVs comprises a second end electrically connected to the second surface of the first substrate.

5. The PoP of claim 2, wherein the first substrate comprises a plurality of second through substrate vias (TSVs) extending therethrough, a first end of the second TSVs disposed at a portion of the second surface not comprising the recess.

6. The PoP of claim 5, wherein one or more of the second TSVs comprises a second end electrically connected to the first semiconductor package.

7. The PoP of claim 5, wherein one or more of the second TSVs comprises a second end physically connected to a respective one of the plurality of routing lines of the redistribution layer.

8. The PoP of claim 1, wherein the first substrate is a substrate of a second semiconductor chip package.

9. The PoP of claim 1, wherein the first substrate is an interposer, and wherein the PoP further comprises:
a second semiconductor package electrically connected to the first substrate via the plurality of first conductive terminals.

10. The PoP of claim 6, wherein the first TSVs have an aspect ratio of 10:1 or higher.

11. The PoP of claim 10, wherein the first TSVs have an aspect ratio that is lower than the aspect ratio of the second TSVs.

12. A package on package semiconductor package (PoP), the PoP comprising:
a first semiconductor package comprising:
a first substrate, the first substrate having a first surface, a second surface opposite the first surface, a redistribution layer comprising a plurality of rerouting lines, and a plurality of first through substrate vias (TSVs) extending therethrough;
a plurality of first conductive terminals disposed at the first surface;
a depression disposed at the second surface, the opening disposed at a center of the second surface; and
a semiconductor chip disposed at the depression, the semiconductor chip comprising a first surface and a second surface opposite the first surface, wherein the first surface of the semiconductor chip opposes the second surface of the first substrate; and
a second semiconductor package electrically connected to the first substrate, the second semiconductor package comprising a second substrate, the second substrate having a first surface and a second surface, wherein the first surface of the second substrate opposes the second surface of the semiconductor chip,
wherein a surface area of the depression is at least a size of a surface area of the second surface of the semiconductor chip and is less than a surface area of the first surface of the substrate.

13. The PoP of claim 12, wherein the depression extends into the first substrate at the second surface at a height equal to at least 50% of a height of the semiconductor chip.

14. The PoP of claim 12, wherein a first end of one or more of the first TSVs are disposed at the first surface of the first substrate and the second end of the one or more first TSVs are disposed at the second surface of the first substrate.

15. The PoP of claim 12, wherein a first end of one or more of the first TSVs are disposed at the first surface of the first substrate and the second end of the one or more first TSVs are physically connected to a respective one of the plurality of routing lines of the redistribution layer.

16. The PoP of claim 12, further comprising a plurality of second through substrate vias (TSVs) disposed in the first substrate, a first end of one or more of the second TSVs disposed at the depression at the second surface of the first substrate and electrically connected to the semiconductor chip and a second end connected to a respective one of the plurality of routing lines of the redistribution layer.

17. The PoP of claim 12, further comprising:
a plurality of second conductive terminals disposed at the first surface of the second substrate, wherein the semiconductor chip is electrically connected to the second substrate via the second conductive terminals.

18. A package on package (PoP) employing a through silicon via (TSV) technique, the PoP comprising:
a lower semiconductor package having first conductive terminals attached to a lower part thereof;
an upper semiconductor package connected to the lower semiconductor package; and
an interposer having a space in at least one surface thereof to accommodate a semiconductor chip and including TSVs for electronically connecting the lower semiconductor package and the upper semiconductor package, and routing lines for re-distributing the TSVs.

19. The PoP of claim 18, wherein the space is formed in a middle of an upper surface of the interposer in a recessed form to receive the semiconductor chip.

20. The PoP of claim 18, wherein the recessed space is formed in a middle of a lower surface of the interposer to receive the semiconductor chip.
